(19) United States
(12) Patent Application Publication
(10) Pub. No.: US 2009/0223555 A1
(43) Pub. Date: Sep. 10, 2009

(54) High Efficiency Concentrating Photovoltaic Module Method and Apparatus

(75) Inventor: Danny F. Ammar, Orlando, FL (US)

Correspondence Address: Danny F. Ammar, 7054 Horizon Cir, Windermere, FL, 34786, US

(73) Assignee: Stalix LLC, Orlando, FL (US)

(21) Appl. No.: 12/043,018

(22) Filed: Mar. 5, 2008

(51) Int. Cl. H01L 31/042

(52) U.S. Cl. 136/246

(57) ABSTRACT

A Concentrating Photovoltaics (CPV) module includes a metal frame, a plurality of Fresnel lenses, a secondary reflective or refractive concentrator, multi-junction solar cells with up to 40% efficiency and a novel heat spreading material. The Fresnel lenses and the secondary concentrator focus the sun over 500 times to maximize the amount of photons collected by the solar cells and converted to electricity. A newly designed soft board material provides coefficient of thermal expansion (CTE) matched carrier for the solar cells and an efficient electrical connectivity method. The carrier board is attached to a specially formulated heat spreader made of graphite. At 40% the weight of aluminum and 18% the weight of copper, this specially formulated material offers thermal heat conductivity that is superior to copper. The combination of the above creates CPV modules with the highest efficiency and lowest cost per Watt.

### PRIOR FILING

This application emanates from a previously filed application No. 60/985,370 Filed on Nov. 5, 2007

### FIELD OF THE INVENTION

The present invention relates to the field of solar power conversion system using Concentrating Photovoltaics (CPV). More specifically, the present invention includes a plurality of Fresnel lenses and a flux homogenizer for concentrating sun rays on to a plurality of multi-layer solar cells. Triple-junction gallium-indium-phosphide/gallium arsenide/gallium solar cells are utilized. The solar cells are mounted to carrier strips made of soft board material; each having a top layer formed from copper traces for cell-to-cell electrical connectivity, and the strips are mounted on a heat spreader formed from graphite fibers. The strips have a coefficient of thermal expansion that is matched to the heat spreader and solar cells. The heat spreader is attached to a rigid, but light weight, honey-comb aluminum base plate. A metal frame is used to house the entire base structure and the Fresnel lenses. Further, water may be circulated through pipes fixed to the frame for producing hot water during the energy conversion process.

### BACKGROUND OF THE INVENTION

The availability of Silicon in nature (sand) has made it popular with the manufacturers of semiconductor devices and quickly became the material of choice for solar cells. Over the last several decades, silicon solar cell technology has become the dominant technology for the majority of photovoltaic (PV) applications. However, despite its good performance and mature manufacturing processes, traditional silicon solar modules remain costly due to their large surface area. In semi-conductor industry, Silicon chips sizes are measured in millimeter square, whereas in solar panels, Silicon area is measured in meter squared. Subsequently, traditional flat-plate PV panels, which can be seen on many rooftops and other facilities, remain costly.

Photovoltaic energy is the conversion of sunlight into electricity through a photovoltaic (PVs) cell, commonly called a solar cell. Concentrating Photovoltaics (CPV) uses lenses and reflectors to concentrate sunlight onto photovoltaic cells, allowing for a decrease in cell size. The main idea is to use very little of the expensive semi-conducting PV material while collecting as much sunlight as possible. In this way sunlight can be collected from a large area using cheap materials, such as plastic, but the power conversion is performed by a specialized high performance solar cell.

The idea of concentrating sunlight onto a small solar cell had been studied and tried for many years. The primary reason for using concentrators is to be able to use less solar cell material. A concentrator makes use of relatively inexpensive materials such as plastic lenses to capture the solar energy shining on a fairly large area and focus that energy onto a smaller area, where the solar cell is located. Sunlight is composed of particles of solar energy called photons, and when these particles strike a photovoltaic cell, they may be reflected, pass right through, or be absorbed. Only a portion of the absorbed photons provides energy to generate electricity.

There are several advantages in concentrator PV systems, as compared to flat-plate systems:
1) Concentrator systems increase the power output while reducing the size or number of cells needed.
2) A solar cell's efficiency increases under concentrated light. How much that efficiency increases depends largely on the design of the solar cell and the material used to make it.
3) A concentrator can be made of small individual cells. This is an advantage because it is harder to produce large-area, high-efficiency solar cells than it is to produce small-area cells.

However, there are several challenges to using current concentrators, which are being addressed by this invention.
1) The concentrating lenses usually have long focal lengths resulting in box shaped modules with substantial height and weight.
2) High concentration ratios introduce heat problems resulting in reduced solar cell efficiency and reliability.
3) Electrical resistance in the cell-to-cell connection results in higher losses and lower efficiency.
4) High concentration ratios require high precision sun trackers

The references listed reflect the state-of-the-art in so far the applicant is aware of at the time of this application. Most of the references disclose typical CPV modules that are configured in a box like structure, with traditional refractive optics such as Fresnel lenses and solar cells that convert sun rays into electricity. None of the references teach the broad concept of incorporating newly engineered materials that substantially increase solar cell efficiency by effectively spreading the heat away from the solar cells. Other newly engineered materials used in the current invention include low cost CTE matched soft boards that act as carriers for the solar cells and provide low loss electrical connectivity. A light weight honey-comb aluminum base plates provide the rigidity needed for the CPV module at a fraction of the weight of other materials. The multi-layer optics used in this invention are unique in that they result in thinner CPV modules that are more aesthetically pleasing and require less material. A secondary concentrator is used to create a homogenous solar flux and to increase the module acceptance angle, thereby reducing the sun tracker accuracy requirements. All these taken in total result in record CPV module efficiency and the lowest cost per watt of electricity generated.

### PRIOR ART

### References Cited

### US Patent Documents

US 2003/0095340 A1 Atwater et al.
US 2004/0246596 A1 Dyson et al.
US 2006/0132932 A1 Dyson et al.
U.S. Pat. No. 4,042,417 Kaplow et al.
U.S. Pat. No. 4,326,012 Charlton
U.S. Pat. No. 4,834,805 Erbert
U.S. Pat. No. 5,091,018 Fraas, et al.
U.S. Pat. No. 5,123,968 Fraas, et al.
U.S. Pat. No. 5,167,724 Jorgensen, et al.
U.S. Pat. No. 5,167,724 Chiang
U.S. Pat. No. 5,482,568 Hockaday
U.S. Pat. No. 5,660,644 Clemens
U.S. Pat. No. 5,851,309 Kousa
U.S. Pat. No. 5,932,029 Stone, et al.
U.S. Pat. No. 5,959,787 Fairbanks
U.S. Pat. No. 6,091,020 Fairbanks, et al.
U.S. Pat. No. 6,316,715 King, et al.
U.S. Pat. No. 6,340,788 King, et al.
U.S. Pat. No. 6,689,949 Ortabasi
U.S. Pat. No. 6,691,701 Roth
U.S. Pat. No. 6,804,062 Atwater, et al.

Atwater et al. focuses on the method of forming a plurality of Fresnel lenses for a micro-concentrator with a magnification of 10 to 100 times. This invention uses a plurality of Fresnel lenses with concentration ratios up to 1000 times. Altwater's lower concentration ratio does not generate as much heat on the PV cell as the current invention's higher concentration. Atwater's system uses aluminum for heat sinking, which provides only 200 W/mK heat spreading, where us this invention uses graphite heat spreading material with a thermal transfer of 500 W/mK. High thermal conductivity of the heat sink is important to maintaining cell efficiency with high concentration.

Dyson et al. describe a polygonal Fresnel concentrator to be used in a distributed environment and to be integrated as part of a building structure, where as this invention describes a flat CPV module that will be used with a 2-axis tracking system. Dyson does not describe in any detail the method of heat sinking or the material used to remove the heat from the solar cells. However, he does mention active cooling using fluid. This invention provides a real solution to the heat spreading problem using passive techniques, which is the key factor in achieving high electrical efficiency.

Kaplow et al. describes a PV system with an optical focusing system made up of an array of lenses to focus incoming sun light onto solar cells. Although this system is similar to the current invention's sun concentration method, it does not provide any details about the heat removal method from the semi-conductor material. Again, in CPV systems heat is the prime reason for solar cell efficiency degradation, which is being addressed by the current invention.

Charlton describes a building block for an exterior wall that captures the sun light and turns it into electricity and heating for the building. The block uses a Fresnel lens to focus the sun and a battery to store the captured energy. Because the building blocks are inherently fixed, the sun concentration can only be very small <10. This is of course different than the current invention's high concentration ratio, which will require sun tracking. Also, because of the high concentration ratio's of the current invention the amount of semi conductor used will be substantially small than in the Charlton system.

Erbert describes a CPV module with concentrating lenses similar to the current invention. However, Erbert concentration is limited to 40 to 50 times. He acknowledges that the heat spreading capability is the limiting factor in his low concentration ratio. The current invention provides a novel method of heat spreading, which allows concentration ratios up to 1000 times.

Fraas et al. describes a multi-cell CPV module which uses Fresnel lenses similar to this invention. The focus of Fraas invention is to improve efficiency of the solar cell by using compound semi-conductor material as a substrate for the booster cell. Although at the time of his invention the record cell efficiency was 34% to 37%, today's multi-junction cell efficiency is above 40%. This invention uses these new multi-junction cells and does not modify them. However, this invention focuses on maintaining the high cell efficiency by providing a unique method of heat removal.

Jorgenson et al. describes a CPV reflector dish that generates a uniform flux for the solar cells. The current invention uses a Fresnel lens with a uniform flux and supplements it with a secondary concentrator, which act as a homogenizer. Jorgenson does not address any of the heat issues created by sun concentration on the solar cell.

Chiang describes a planar CPV module similar to the current invention. The focus of his invention is on the modularity, self containment and sealing of the individual CPV cells to improve reliability and producibility. This invention achieves similar goals but uses different techniques for creating multi-cell modules that do not rely on single cell modularity, instead an integrated module is proposed. Chiang also uses metal heat spreader, which are limited in thermal conductivity. This invention uses graphite material heat spreader, which provides superior thermal conductivity at a fraction of the weight and cost of metal heat spreaders.

Hockaday describes a method of concentrating sun using a matrix of small mirrors.

O'neall et al. describes a linear CPV module with individual metal heat sinks underneath each solar cell. The focus of his invention is to reduce losses in the electrical interconnect system for the cells and to provide adequate cooling for the cells. This invention uses a different method for the electrical interconnects and the heat sinking. This invention uses soft board material with wide cooper traces to interconnect the cells with minimal electrical losses. As for the heat sinking, this invention preferred method of cooling is to use a thin layer of graphite material, which achieves a typical temperature rise in the cells of <11 degrees.

Clemens describes a foldable CPV systems best suited for satellite and space craft applications.

Kousa describes a method for directing and concentrating solar energy for CPV systems using a building structure. The current invention focus is on the CPV

| Foreign Patent Documents | Country & Date |
|---|---|
| WO 03/105240 A1 | WIPO; Dec. 18, 2003 |

### Other Publications

E. Richards, “Sandia's Baseline 3 Photovoltaic Concentrator Module”, 20^{th} IEEE Photovoltaic Specialists conference, 1988, pp 1318-1323.

S. L. Levy, conf. Record, 17ty IEEE Photovoltaic Specialists Conference, (1984), pp. 814-819

L. M. Fraas et al., IEEE AES Magazine, November 1989, pp. 3-9

W. Altenstadt et al., Physica, vol. 129B, pp. 497-500 (1985)

J. E. Avery et al., Space Photovoltaic Research & Technology (SPRAT), 1989

### SUMMARY OF THE INVENTION

The concentrating PV module of the current invention provides the lowest cost per watt of electricity generated by a solar module. The present invention combines the use of multi-junction solar cells with a novel approach to sun concentration using a multiplicity of Fresnel lenses and unique approaches to heat spreading and electrical loss minimization, to provide solar modules with up to 35% efficiency.

The solar module of the current invention uses triple junction Gallium-Indium-Phosphide/Gallium Arsenide/Gallium (InGaP/InGaAs/Ge) sollar cell, which reduces the amount of semi conductor material used to generate electricity by up to 600 times as compared to flat Silicon solar panels. A 1 cm² triple junction InGaP/InGaAs/Ge solar cell produces up to 18 watt under 500:1 sun concentration, where is a 1 cm² Silicon cell produces only 0.03 watts with no sun concentration.

The solar concentration optics of the current invention uses a multiplicity of negative and positive Fresnel lenses to optimize the sun concentration while reducing the thickness of the solar module by at least 50%. Typical concentrating optics have long focal lengths resulting in box shaped modules with several inches thickness.

The most critical issues in solar contractor module design are selection of material and process for mounting the solar cells to a cooling surface, achieving high thermal conductivity, and interconnecting the cells with very low electrical resistance. This invention uses a uniquely formulated thin strips of coefficient of thermal expansion (CTE) matched carrier to mount the solar cells, and then attaches the carrier strips to the heat spreading material, which is attached to the base plate. The solar cells are attached to the carrier strip using solder or compliant conductive epoxy with high thermal coefficient. The CTE matched strips are made-up of a very low cost soft-board material designed specifically for this application.

The top layer of the carrier strip of the current invention is made up of copper traces, which provide cell-to-cell electrical interconnection, for multi-cell modules, with less than 0.01 Ohm resistance resulting in less than 0.1 V drop in voltage and <0.5 watt power loss.

When sun radiation is concentrated, so is the amount of heat produced. Cell efficiencies decrease as temperatures increase, and higher temperatures also threaten the long-term stability of solar cells. Therefore, the solar cells must be kept cool in a concentrator system. This invention's heat spreader is made of graphite fibers, one of the newest types of heat-spreader materials. At 40% the weight of aluminum and 18% the weight of copper, graphite offers excellent thermal conductivity. The graphite heat spreaders offer thermal conductivity up to 500 W/mK as compared to about 200 W/mK for aluminum. The heat spreader of the current invention is anisotropic, conducting heat well along its x and y axes but less in the z-axis. As a result, it conducts the heat longitudinally away from the source to the metal frame and thus minimize hot spots. Price-wise, graphite material is competitive with other heat-spreader materials, so it is appropriate for solar panels.

The current invention also provides unique methods for additional thermal management by adding heat sinks under the individual cells or to the module metal frame. In addition, the current invention provides a novel method for harvesting free hot water by actively circulating water through pipes embedded in the module's metal frame. The hot water can be used for heating space in commercial and residential buildings.

The concentrating solar module of the current invention is designed for ease of assembly. All components can be assembled with standard tools, using commercially available materials.

### BRIEF DESCRIPTION OF THE DRAWINGS

Other objects, features and advantages of the present invention will become apparent from the detailed description of the invention which follows, when considered in light of the accompanying drawings which:

FIG. 1 is a fragmentary block diagram of a typical grid-connected photovoltaic solar system.

FIG. 2 shows prior art reflective type solar concentrator.

FIG. 2A shows prior art refractive type solar concentrator.

FIG. 2B shows prior art refractive solar concentrator with curved shaped lens.

FIG. 2C shows prior art solar concentrator module using curved shaped Fresnel lens.

FIG. 3 is an isometric view, partially cutaway, of a high concentration photovoltaic module, typically used with sun tracking, having eighteen concentrator cells.

FIG. 3A is an isometric view of a medium concentration photovoltaic module, typically used in fixed installations, having eighteen concentrator cells.

FIG. 4 shows an example of this invention's sun concentrator optics having 2 positive Fresnel lenses.

FIG. 4A shows an example of this invention sun concentrator optics having one Fresnel lens and a secondary flux homogenizer

FIG. 4B shows the current invention's medium concentrator optical system having one negative and one positive Fresnel lens.

FIG. 4C shows an example of this invention's low to medium concentrator optics having one dome-shaped Fresnel lens and a flat Fresnel lens.

FIG. 4D shows an isometric view and a cross sectional view of a flux homogenizer of the current invention.

FIG. 4E shows the secondary reflector/homogenizer ability to widen the sun tracking acceptance angle

FIG. 5 shows the multi-junction solar cell ability to capture different parts of the light spectrum and thereby achieving such high efficiency.

FIG. 5A shows the solar cells efficiency and electricity generation capacity of Silicon and multi-junction (GaInP/GaAs/Ge).

FIG. 6 shows detailed views of the front and back sides of the CTE matched strip with expanded views of the solar mounting areas and a cross section of the assembly.

FIG. 6A shows a top view of a 20-cell solar module electrical connectivity of the current invention.

FIG. 7 shows the heat spreading concept of the current invention.

FIG. 7A shows the base plate panel which includes a honeycomb core used for increased rigidity and module stifness.

FIG. 8 is a cross-sectional view (not to scale) of three concentrator cells illustrating the heat spreading method of the current invention.

FIG. 8A is a cross-sectional view (not to scale) of a single concentrator cell illustrating the double heat-spreader method of the current invention

FIG. 9 shows a cross sectional view of a solar cell with a heatsink underneath it and an isometric view of the heatsink.

FIG. 10 shows a top view and an isometric view of heatsinks added to the frame of an 18-cell solar module of the current invention.

FIG. 11 Shows a cross sectional view of a single solar cell and a top view of an 18-cell module with water cooling option.

FIG. 12 shows an exploded view of the base plate sub-assembly shown the module assembly process.

FIG. 13 shows an isometric view of the module frame shape, which holds the optics and the base plate sub-assemblies.

### DETAILED DESCRIPTION OF THE PREFERRED EMBODIMENTS

The present invention will now be described more fully hereinafter with references to the accompanying drawings, in which preferred embodiments of the invention are shown. This invention may, however, be embodied in many different forms and should not be constructed as limited to the embodiments set forth herein. Rather, these embodiments are provided so that this disclosure will be thorough and complete, and will fully convey the scope of the invention to those skilled in the art. Like numbers refer to like elements throughout, and prime notation is used to indicate similar elements in alternative embodiments.

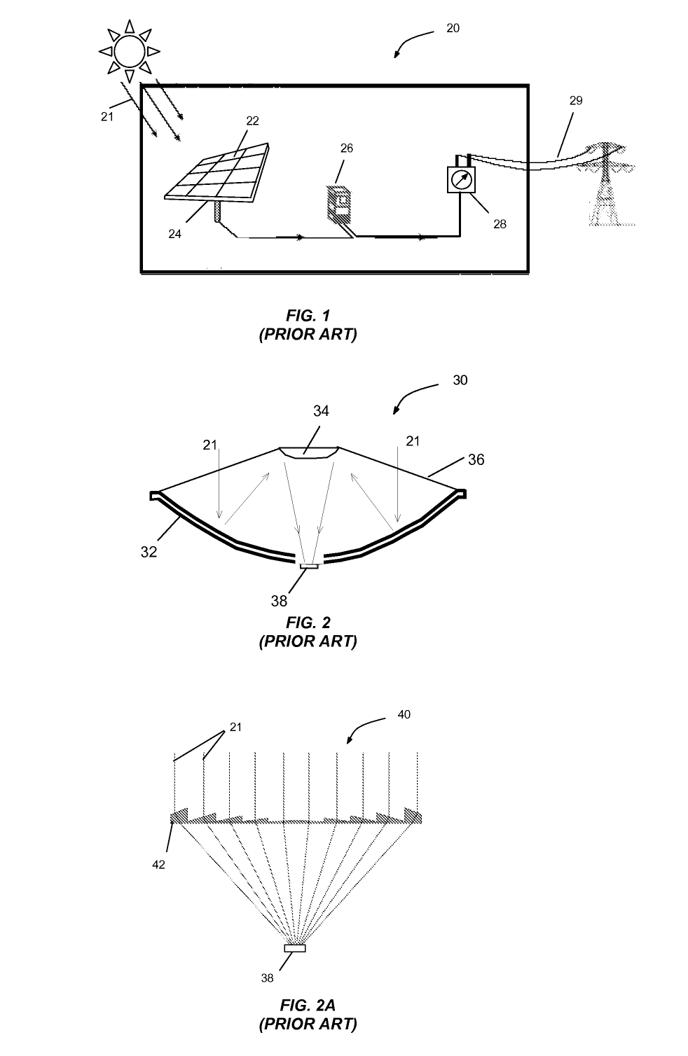

FIG. 1 shows a typical grid-connected photovoltaic solar system 20. The solar array 22 consists of one or more PV (photovoltaic) modules which convert sunlight 21 into electricity. The sun tracker 24 is a device that rotates in 1-axis or 2-axes to track the sun across the sky throughout the day to keep the sun rays directly on the solar array. The DC-AC inverter 26 converts the DC power produced by the PV array into AC power consistent with the voltage and power quality requirements of the utility grid. The power meter 28 measures the amount of electricity being generated and released to the power grid 29. The solar array cost represents around 50 to 60% of the total installed cost of a typical grid-connected Solar Energy System.

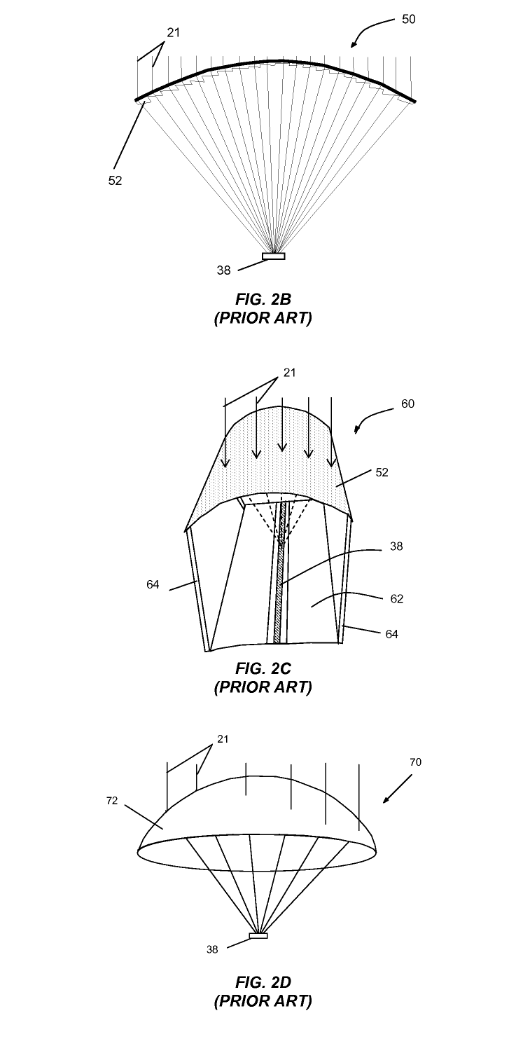

FIG. 2 shows prior art reflective type solar concentrator 30. This type of concentrator works in a manor very similar to microwave antennas. The main reflector 32 collects the sun rays 21 and directs them to a sub-reflector 34, which is held in place with a bracket 36. The sub-reflector in turn focuses the rays onto the solar cell 38. This method of solar concentration is widely used in today's CPV systems.

FIG. 2A shows prior art refractive type solar concentrator 40. This sun concentrator type employs a Fresnel lens 42, which uses a miniature sawtooth design to focus incoming sun light 21 on to the solar cell 38. When the teeth run in straight rows, the lenses act as line-focusing concentrators. Whereas when the teeth are arranged in concentric circles, light is focused at a central point.

FIG. 2B shows prior art refractive solar concentrator 50 with curved shaped lens. This type of concentrator employs a curved Fresnel lens 52 to focus the sun rays 21 on the solar cell 38.

FIG. 2C shows prior art solar concentrator module 60 using curved shaped Fresnel lens. In this case, the teeth of the lens 52 run in straight rows act as line-focusing concentrators. The sun rays 21 are focused on a long strip of solar cell 38, which is mounted on a base plate 62. The base plate and the lens are maintained at a fixed distance relative to each other using the mounting brackets 64.

FIG. 2D shows prior art solar concentrator 70 using a dome-shaped lens. The most commonly used lens in this type of application is an injection-molded plastic Fresnel lens. Acrylic plastic is the most widely used material for these type of lenses and Its transmittance is nearly flat and almost 92% from the ultraviolet to the near infrared. The lens 72 captures the sun rays 21 from different direction, thereby eliminating the need to track the sun and focuses them on the solar cell 38.

High concentration systems were not widely available because of the lack of cost effective solar cells and packaging methods. Also, mechanical structures for concentrating solar systems have been configured with bulky, box-type module construction and are difficult to manufacture, transport and install. This invention provide a unique approach to sun concentration that eliminates the box-like modules and integrates the Fresnel lenses and solar cells into one simple highly efficient assembly that greatly reduces manufacturing costs.

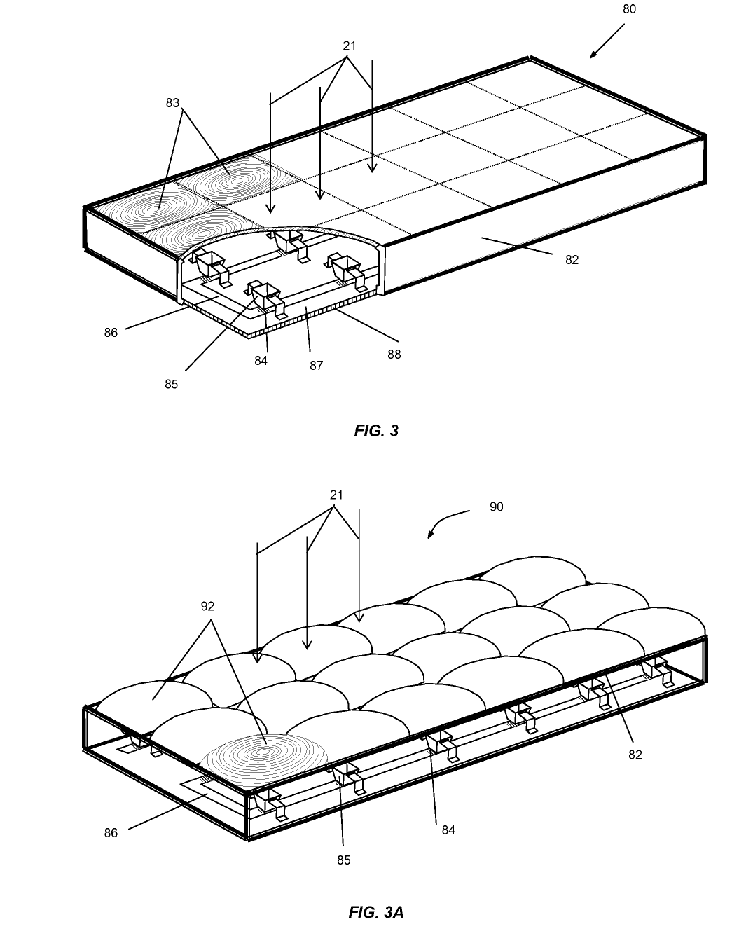

FIG. 3 shows an isometric view of the present invention high concentration photovoltaic module 80 having 18 concentrator cells held together by a metal frame 82, which provides the required rigidity and strength to be able to mount the module in harsh outdoor environment. It should be understood that although an 18-cell module is illustrated in FIG. 3, any number of solar cells can be used. The metal frame 82 is made-up of low cost extruded aluminum with pockets used to hold the Fresnel lenses, which can be manufactured on a single sheet of acrylic plastic, and the base assembly which includes the solar cells. This module combines the use of multi-junction solar cells 84 with a novel approach to sun concentration using a multiplicity of Fresnel lenses 83 and a relective or refractive flux homogenizer 85, and unique approaches to heat spreading and electrical loss minimization, to provide high efficiency solar energy conversion to electricity. Each of the Fresnel lenses 83 is made up of one or more lenses bounded together to form the basic concentrating optics for each cell, while minimizing the focal length and thereby reducing the module thickness. The lens structure will be discussed in detail in the next few paragraphs. The multiplicity of Fresnel lenses 83 are used to collect the sun rays 21 and focuses them up to 1000 times into a secondary concentrator 85, which create a homogenous flux for the solar cells 84. The solar cells 84 of the current invention are made of multi-junction (InGaP/InGaAs/Ge) semiconductor material, which provides up to 40% efficiency in solar energy conversion to electricity. The solar cells 84 are mounted on a specially formulated strip of soft board material 86, which is CTE matched to the semiconductor material of the solar cells 84 and provides the cell-to-cell electrical connection with minimal losses. The strips of soft board material are bonded to a heat spreader 87, which is made up of a layer of graphite material. The heat spreader 87 is in turn bonded to a honeycomb aluminum base plate 88. The graphite material of the heat spreader 87 provides unsurpassed heat spreading capability and offer thermal conductivity up to 500 W/mK as compared to about 200 W/mK for aluminum. The graphite weighs 60% less than aluminum and 82% less than copper.

FIG. 3A shows an isometric view of a medium concentration photovoltaic module 90, typically used in fixed installations, having eighteen concentrator cells held together by a metal frame 82. This module is similar to FIG. 3 module except it uses dome-shaped Fresnel lenses 92 to capture the sun rays 21 without tracking the sun. The dome shaped Fresnel lens provides a wide acceptance angle to sun rays and therefore no sun tracking will be required.

The Fresnel lens structure of the current invention will now be described more fully hereinafter with references to the accompanying drawings, in which preferred embodiments of the invention are shown.

Typical concentrating optics have long focal lengths resulting in box shaped modules with substantial height. This invention addresses this issue with a unique approach of using a composite lens design.

The design quality of the optical elements in a solar photovoltaic concentrator is the key to enable the exploitation of the efficiency potentials of multi-junction devices. The cells require homogeneous flux over the cell area and reproduction of the solar spectrum, for which the thickness of the layers was designed.

Lenses may be combined to form more complex optical systems. A typical Fresnel lens has a focal length that is about half of its diameter. For example a 10 inch diameter lens will have a 5 inch focal length. In order to design PV modules with thin practical frame similar to the normal PV panels, the condenser lens becomes impractically “fast”—that is, its diameter is greater than twice its focal length (≦f/0.5). To shorten the focal length, this invention uses two Fresnel lenses, grooves together, to form a two-lens element with a focal length equal to the geometric mean of the two focal lengths used in the pair. For example, if each lens has a 5 inch focal length, the pair will have an effective focal length of 2.5 inches. To avoid degradation, the 2 lenses have exactly the same groove density and that they are well centered with respect to each. The focal lengths need not be equal, so that conjugate ratios other than 1:1 are easily achieved. The simplest case is when lenses are placed in contact. If 2 lenses of focal lengths f₁ and f₂ are “thin”, the combined focal length f of the lenses can be calculated from:

1/f=1/f₁+1/f₂

Since 1/f is the power of a lens, it can be seen that the powers of thin lenses in contact are additive. If two thin lenses are separated by some distance d, the distance from the second lens to the focal point of the combined lenses is called the back focal length (BFL). This is given by:

BFL=f₂(d−f₁)/[d−(f₁+f₂)]

Note that as d tends to zero, the value of the BFL tends to the value of f given for thin lenses in contact.

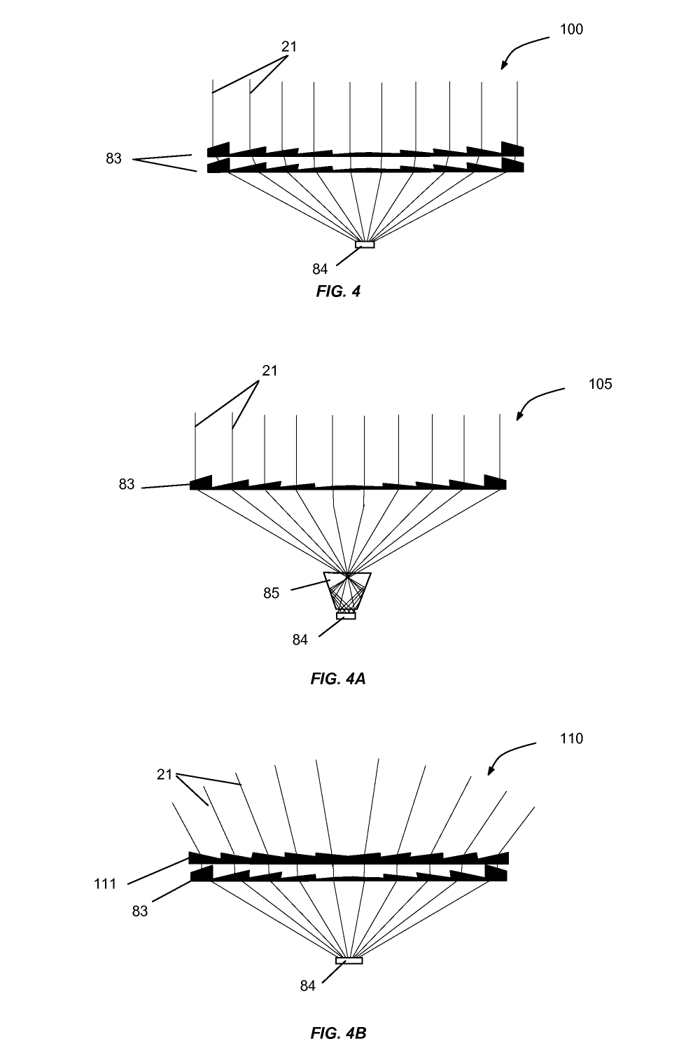

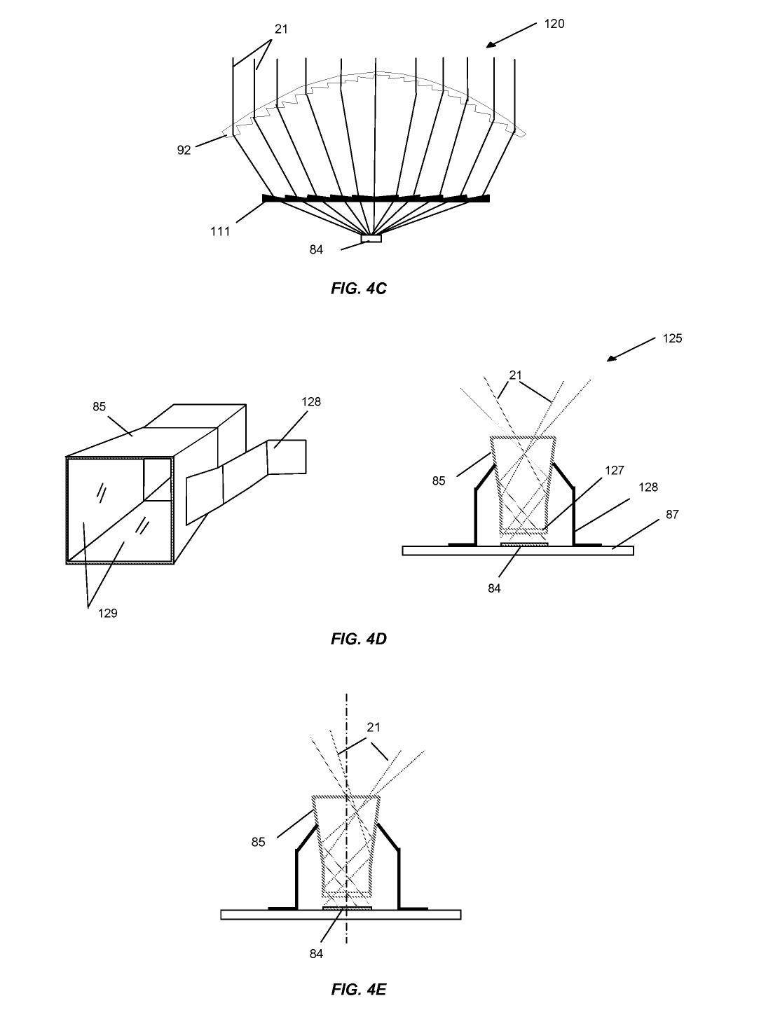

Using a combination of positive, negative and shaped non-imaging Fresnel lenses the current invention produces concentration methods that result in shorter focal lengths. FIG. 4 shows an example of this invention's sun concentrator optics 100 having 2 positive Fresnel lenses 83. The first lens bends the solar rays 21 towards its focal point and the second lens bends the rays further towards the solar cell 84 at a shorter focal point. This multi-lens method enables low, medium and high level of sun concentration. Up to 1000:1 sun concentration has been demonstrated. At high concentration levels, sun tracking is required to maintain efficiency. There are many low cost tracker suppliers that provide both active and passive sun trackers. The tracking systems track the sun to maximize energy production throughout the day. The secondary concentrator is used to increase the module acceptance angle and reduce the tracker accuracy.

FIG. 4A shows an example of this invention's concentrator optics 105 having one Fresnel lens 83 and one secondary reflective or refractive concentrator 85 used to create a homogenous flux for the solar cell 84. The secondary concentrator is also used to increase the module acceptance angle while tracking the sun. The acceptance angle with this design is expected to be between +/−0.5 and +/−1 degree. Without the secondary concentrator the acceptance angle of the module is less than +/−0.5 degree, which requires an accurate sun-tracker.

FIG. 4B shows an example of this invention's medium concentrator optics 110 having one negative Fresnel lens 111 and one positive Fresnel lens 83. The first lens captures rays 21 from a wide angular area thus eliminating the need for tracking. The second lens bends the rays 21 towards the solar cell 84 near the focal point.

Low to medium sun concentration can be achieved by this invention's optical system even with fixed module installations. The dome shaped Fresnel lens used in the concentrator system is optimized as a low loss collector. A key breakthrough in the development of the dome-shaped lens was the successful injection moulding of the lens. This process allows a rapid and inexpensive means for manufacturing high quality lenses for use in a concentrator system. FIG. 4C shows an example of this invention's low to medium concentrator optics 120 having one dome-shaped Fresnel lens 92 and a flat Fresnel lens 111. The first lens captures sun rays 21 from a wide angular area thus eliminating the need for tracking. The second lens bends the rays towards the solar cell 84 near the focal point.

In order to reach their maximum efficiency, CPV cells require a uniform light distribution. In some case the Fresnel lenses may not be able to produce a uniform flux over the solar cell because of sun tracking errors, lens-to-solar cell misalignment or lens imperfection. FIG. 4D shows a secondary reflector/homogenizer system 125 that can be implemented with any of this invention's CPV modules. The flux homogenizer 85 is used to redirect the rays 21 and create a uniform flux. Such device is known as a kaleidoscope. It consists of a hollow tube with plane sidewalls having reflective internal surfaces 129. Focused rays 21 from the Fresnel lens enter on one end of the kaleidoscope and undergo a number of reflections from the side walls 129 in order to create a more uniform intensity at the solar cells. The kaleidoscopes and their use in solar spectrum uniformity generation have been around for a long time and were subjects of many prior inventions. The key element in this invention is the addition of clear windows 127 made of low iron glass at the low end of the kaleidoscope to reduce the amount heat transferred directly to the solar cells. The concentrated heat in the kaleidoscope is dissipated through it metal body, which is heat sunk to the graphite heat spreader material. The homogenizer may be mounted directly above each of the solar cells 84 using the support legs 128, which are surface mountable using epoxy or solder. The other benefit of the homogenizer is its ability to increase the sun tracking angular error tolerance as shown in FIG. 4E, so that the tracker does not have to precisely track the sun. The homogenizer increases the module acceptance angle up to +/−1 degree.

The module packaging of the current invention and its unique thermal management solution will now be described more fully hereinafter with references to the accompanying drawings, in which preferred embodiments of the invention are shown. High sun concentration introduces heat. When sun radiation is concentrated, so is the amount of heat produced. Cell efficiencies decrease as temperatures increase, and higher temperatures also threaten the long-term stability of solar cells. Therefore, the solar cells must be kept cool in a concentrator system.

This invention addresses the heat issues in 3 unique methods: 1) Use of high efficiency multi-junction cells, 2) Packaging and use of novel thermal solutions, and 3) Passive and active cooling

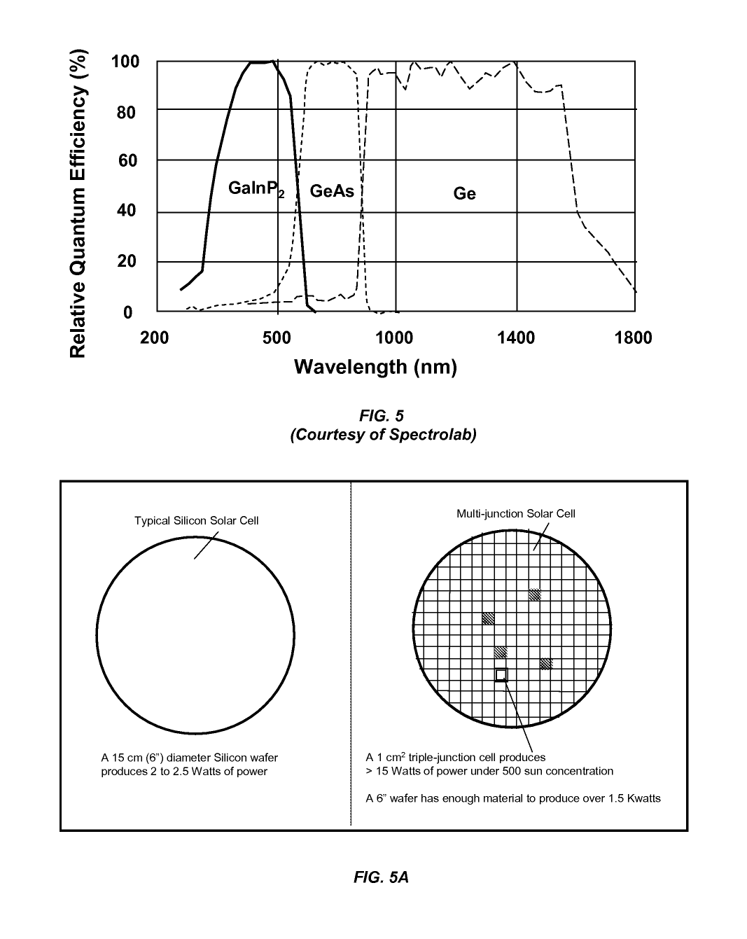

One of the main obstacles to sun concentration has been that the Silicon solar cells became very inefficient when exposed to concentrated sunlight. Silicon solar cells provide a best 15% efficiency under nominal conditions. In the last few years, new multi-junction solar cell technologies have emerged. The concentrator system described here uses triple junction Gallium-Indium-Phosphide/Gallium Arsenide/Gallium (GaInP/GaAs/Ge) cells with up to 40% efficiency, available from such companies as Spectrolab (a Boeing company). These multi-layer cells were commonly used on spacecrafts and satellites because of their high efficiency, but have been prohibitively expensive for terrestrial application. However, recent breakthroughs in this technology have made these cells more affordable. FIG. 5 (courtesy of Spectrolab) shows how the different semiconductor materials are used to capture a different part of the light spectrum and thereby achieving such high efficiency. The multi-junction cells capture solar rays from 400 nm to 1500 nm wavelengths. FIG. 5A shows a comparison between Silicon and multi-junction (GaInP/GaAs/Ge) solar cell efficiency and electricity generation from a 6 inch wafer. The Silicon wafer generates about 2 to 2.5 watts, whereas the (GaInP/GaAs/Ge) wafer generates about 1.5 Kwatt of power.

The most critical issues in solar contractor module design are selection of material and process for mounting the solar cells to a cooling surface, achieving high thermal conductivity, and interconnecting the cells with very low electrical resistance.

The higher efficiency multi-junction cells are very small, typically ≦1 cm², as compared to Silicon cells used in traditional panels. The smaller size cells open the way to new packaging methods for solar concentrator modules with low cost materials. The main obstacle to achieving low cost packaging with good thermal conductivity has been the mismatch between the coefficient of thermal expansion (CTE) of semiconductor materials such as Si or GaAs, and good thermal metals such as aluminum and cooper.

The coefficient of thermal expansion of Silicon and other semiconductor multi-junction materials are between 4 and 7 ppm/deg C. The CTE of low cost metal, such as aluminum and copper, are >16 ppm/deg C. For proper heat sinking, the solar cells must somehow be connected to a metal carrier or plate. Large CTE mismatch causes the semiconductor material to crack as the carrier material shrinks and expends are different rate over temperature. Traditionally, small semiconductor modules use CTE matched carrier material, such as copper tungsten (CuW) or aluminum silicon carbide (AlSiC). However, these materials are relatively expensive and provide no commercial viability for solar module fabrication.

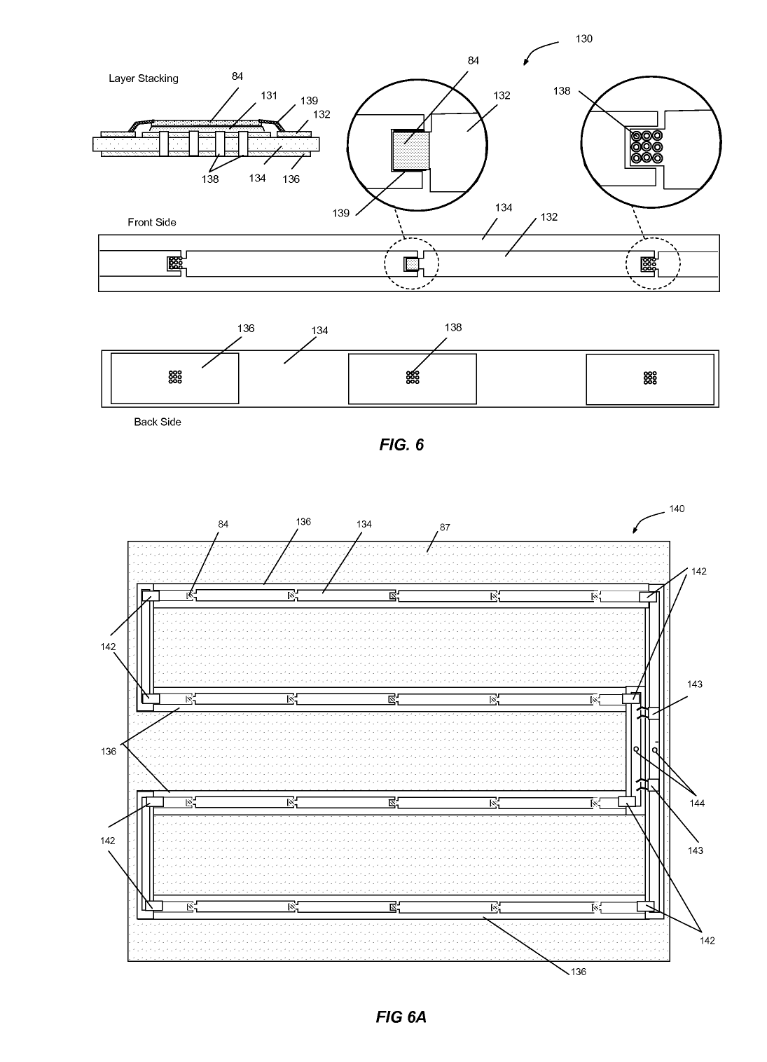

This invention uses a uniquely formulated thin strips of coefficient of thermal expansion (CTE) matched carrier to mount the solar cells, and then attaches the carrier strips to the heat spreading material, which is attached to the base plate. FIG. 6 shows details views 130 of the front and back sides of the CTE matched strip with expanded views of the solar mounting areas and layer stacking. The solar cells 84 are attached to the carrier strip using solder or compliant conductive epoxy with high thermal coefficient 131, such the 6030-HK epoxy made by Diemat. The CTE matched strips are made of a very low cost laminate material designed specifically for this application. The construction of the laminate provides exceptional mechanical stability and CTE matching to the solar cell's material. This laminate can be drilled, milled, and plated using standard methods for PTFE/woven fiberglass materials. It exhibits virtually no moisture absorption during fabrication processes. The soft board has one copper layer on the top 132, which may be gold or silver plated for better electrical conductivity, a thin layer of woven glass material 134, and a layer of copper in the bottom 136. Heat is transferred from the solar cell to the bottom layer using heat sink vias 138. The solar cell's positive posts are connected to the electrical traces 132 with special metal busses 139 that are bonded to the cell and to the electrical traces with solder or conductive epoxy.

One of the most important design considerations in the solar module is to minimize electrical resistance where the external electrical contacts carry off the current generated by the cell. Reducing electrical resistance is important in solar cells connectivity. The electrical connections must have extremely low loss. The best material to achieve this function is copper. For example, a 0.5 oz copper layer with a 22 mm width can provide cell-to-cell connections (25 cm apart) with less than 0.01 ohm resistance. Assuming that each cell generates 7 amps of current at 2.8 V, the total voltage drop in the electrical trace will be <0.07 V and the total power dissipated in the line will be 0.5 watts. FIG. 6A shows a top view of a 20-cell solar module electrical connectivity 140 of the current invention. The cells, which are mounted on the CTE matched strips 136, are connected electrically through the metal traces 134. The CTE matched strips are compression bonded to the heat spreader 87 and are connected to each other through the use of a wide metal strip 142, which is soldered or epoxy bonded at both ends. The 20 cells are divided into 2 groups of 10 cells each. Each group of 10 cells 84 are connected in series, therefore the output voltage will be additive. A bypass diodes 143 is connected to each group. Since the current of a cell is proportional to its illumination, a shaded cell in series-connected module or string will “choke” the current through the other cells. To prevent this from happening, a bypass diode a placed across a fraction of cells in a module, in this case half of the cells in a module. In this way if a portion of the module is shaded, the bypass diode can “bypass” the current around those cells, preventing the “current choking” from happening. Unfortunately, the voltage drops to a fraction of a volt, greatly reducing the power available from the bypassed cells. Nonetheless, the total current through the module is not compromised and the output power of a partially shaded module might drop to half of its potential output, which is better than something close to zero. The positive and negative posts 144 are used to solder 2 wires which will carry the DC current from the front to the back of the solar module where the junction box (not shown) is located.

This invention provides a number of unique thermal-management methods using both passive and active systems. The challenge is not only to remove heat from the sollar cell that is dissipating it, but also to get that heat to where you want it to go. The conventional approach is to employ a copper or aluminum heat spreader, often coupling it with a heat sink or active liquid cooling, but this invention offers a passive alternative with lower weight plus directed heat flow. The general rule-of-thumb is that the concentrated heat created by the concentrating the sun must be spread over an area equal to or larger than the size of lens. The most effective way to spread the heat from a small solar cell (1 cm²) over much large area is to use heat spereading materials with excellent thermal conductivity.

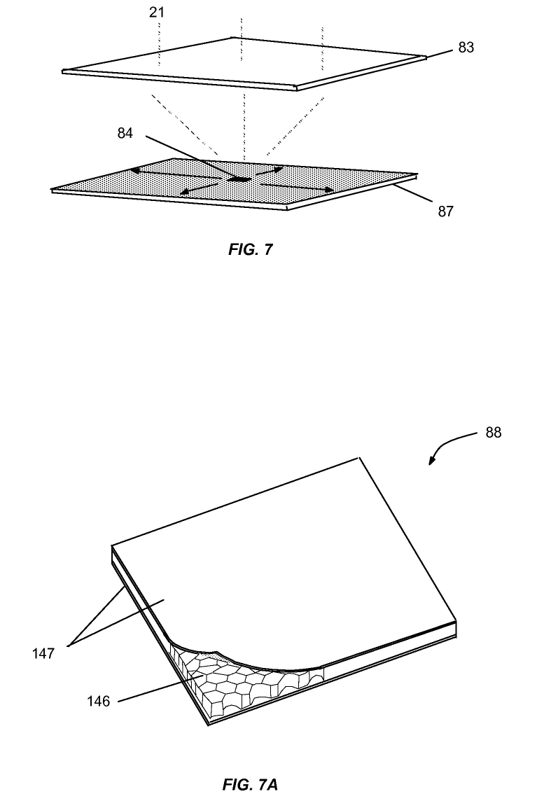

FIG. 7 shows the heat spreading concept of the current invention. As the Fresnel lens 83 focuses the sun rays through the secondary concentrator 85 onto the solar cell 84 with up to 1000 times concentration, the heat from the sun is also focused on the small area of the solar cell. This invention's heat spreader 87 is made of graphite fibers, one of the newest types of heat-spreader materials. At 40% the weight of aluminum and 18% the weight of copper, graphite offers excellent thermal conductivity. The material is produced from expanded natural graphite flake, which is pressed and rolled out into long sheets and then cut to the required size for heat spreaders. This pliable spreader is anisotropic, conducting heat well along its x and y axes but less in the z-axis. As a result, it conducts the heat longitudinally away from the source. The graphite heat spreader enables radiation cooling equivalent to non-concentration temperature. The use of the graphite heat spreader in CPV modules is one of the key innovations in this invention. Thermal efficiency of the graphite heat spreader has been measured on practical samples CPV cells and have shown a temperature rise in the solar cells of less than 15 deg C. above ambient as compared to 60 degree rise when aluminum heat spreader is used and 76 degree rise when the solar cells were mounted on a ceramic carriers.

The sun concentrator panel use the graphite material to spread the heat away from the solar cell towards the aluminum frame and thus minimize hot spots. By distributing heat evenly in two dimensions, heat spreaders eliminate “hot spots” while simultaneously reducing touch temperature in the third dimension. The graphite heat spreaders offer thermal conductivity of 240 to 500 W/mK as compared to about 200 W/mK for aluminum. Price-wise, it's competitive with other heat-spreader materials, so it is appropriate for solar panels.

FIG. 7A shows an isometric view of the base plate 88, with a lift-up of the top layer. The base plate is made from aluminum honeycomb core 146 expanded into a hexagonal structure sandwiched by the aluminum facings 147 which are then bonded together by a layer of adhesive. Sandwich panels utilizing aluminum honeycomb cores result in lightweight, high strength structures that are very rigid and remain perfectly flat throughout their service life. Aluminum honeycomb panels have the best strength to weight ratio of any material available. The key characteristics of the base plate are:
a) Light weight with high stiffness strength. The light weight is critical for reducing transportation cost. The stiffness is need to maintain the distance between the Fresnel lenses and the solar cell constant.
b) Heat dissipation. The based plate plays a key role in helping maintain high solar cell efficiency. The thermal design of this invention's CPV module is discussed later in more details.
c) Corrosion, fungi, chemical, moisture resistant: This is an important feature for solar modules that are expected to work in an outside environment for at least 25 years
d) Vibration dampening: Under certain wind conditions, vibration may become excessive if the module does not have a much higher resonant frequency
e) Fire retardant: Although fires are not common in solar module, metal such as aluminum are not easily ignited and do not spread fire.

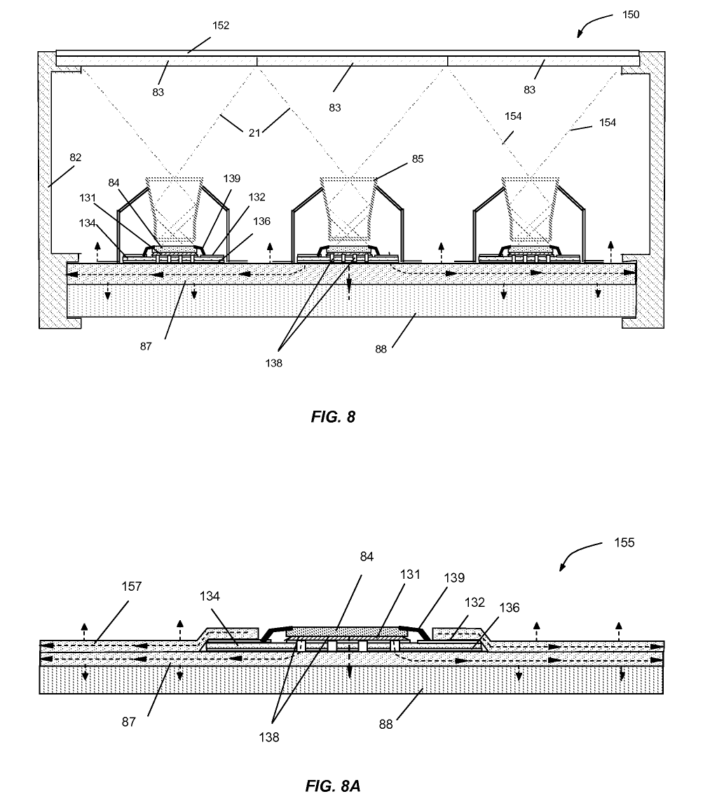

FIG. 8 is a cross-sectional view (not to scale) of 3 concentrator cells 150 illustrating the heat spreading method of the current invention. The Fresnel lenses 83, which are protected from the outside elements by a thin layer of Fluoropolymer film 152, concentrate the sun rays 154 into a secondary concentrator 85 which creates a homogenous solar flux for the solar cells 84, which transforms the photons into electricity. The layer of Fluoropolymer film weights less then 2% of an equivalent for Fe float glass and provides nearly 95% transmissivity of solar rays. The solar cell is attached to a strip of CTE matched material using solder or compliant epoxy 131 with excellent thermal conductivity. The thermal vias 138 are used to transfer the heat from the solar cell to the heat spreader 87. The bottom of the CTE matched strip 136 is directly bonded to the graphite heat spreader 87 through compression. The heat transfer from the solar cell 84 to the frame 82 is shown with arrows. As previously discussed the heat transfer in the graphite material is mainly lateral and longitudinal. This method eliminates hot spots and allows the solar cell to remain relatively cool and thereby maintain its efficiency. Some of the heat is also dissipated in the base plate, which is also a great heat sink due to its honeycomb structure.

FIG. 8A is a cross-sectional view (not to scale) of a single concentrator cell 155 illustrating the double heat spreading method of the current invention. In addition to graphite heat spreader 87 under the solar cell, a second graphite heat spreader 157 is added on the top. The top heat spreader layer covers the entire top surface except for the areas where the solar cells are mounted. The solar cells are exposed to the concentrated solar energy from the Fresnel lenses through cut-out in the top graphite heat spreader layer. In addition to providing more heat spreading capability and removing the heat away from the solar cells, this top graphite layer also provides protection for the electrical connectivity layer 132 and keeps it relatively cool to minimize electrical loses.

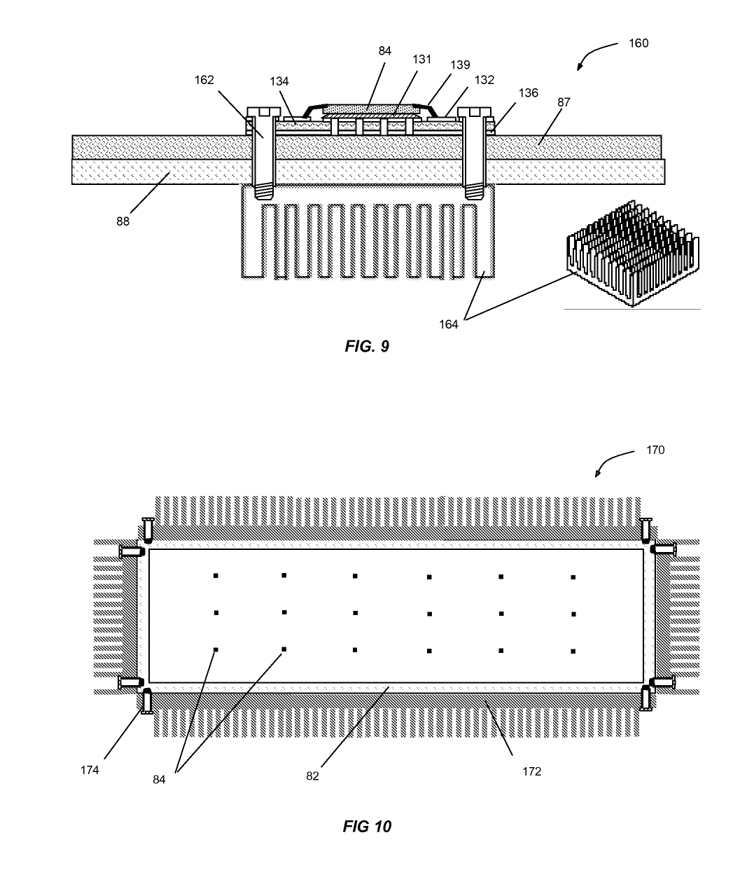

If additional solar module cooling is needed, then external heat sinks can be added underneath each of the solar cells or to the frame. A heatsink is a metallic device with high thermal conductivity. It increases the cooling surface area. FIG. 9 shows a cross sectional view of a solar cell with a heat sinks underneath it and an isometric view of the heatsink 160. The heatsink 164 attaches to the back plate under the solar cell, with screws 162. Using its large surface area, the heatsink lowers the cell's temperature by radiating its heat into the surrounding air. Heatsinks are made from an aluminum or copper alloy that has fins either shaped as parallel plates or with round, square, or elliptical pins. These heat sinks are commercially available at low cost.

FIG. 10 shows a top view and an isometric view of heatsinks added to the frame of an 18-cell solar module 170. The heatsink 172 are attached to the frame with screws 174. The heat sink will increase the surface area used to release the heat collected in the frame.

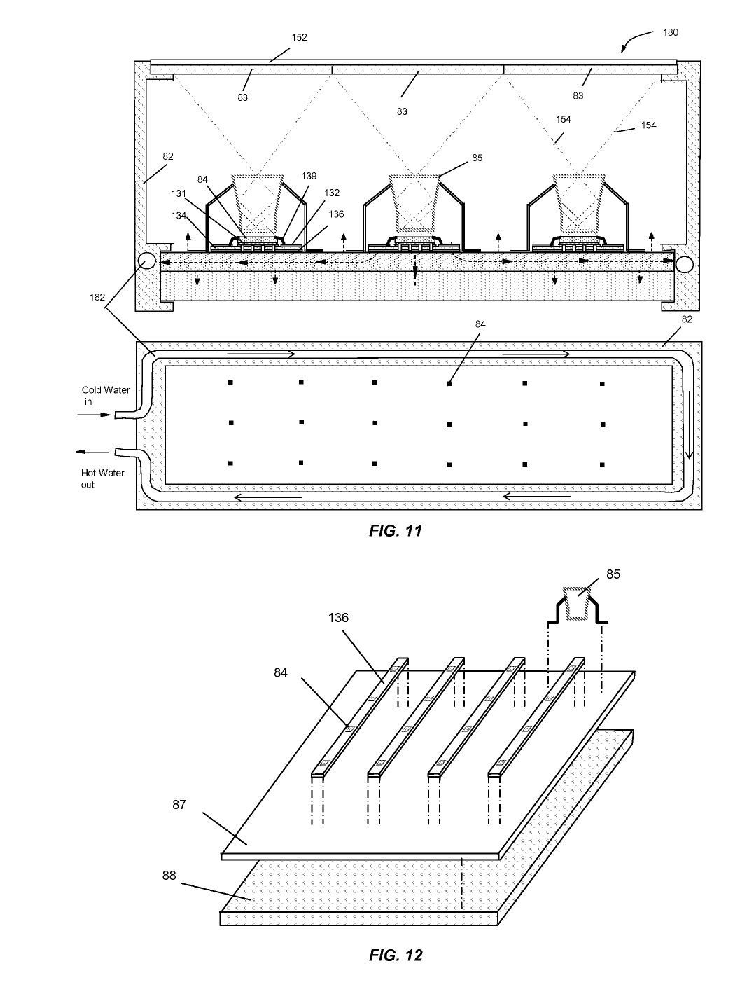

In addition to the above mentioned passive cooling techniques, the current invention provides a novel method for harvesting free hot water by actively circulating water through pipes embedded in the module's metal frame. The hot water can be used for heating space in commercial and residential buildings. FIG. 11 Shows a cross sectional view 190 of a single solar cell and a top view of an 18-cell module with water cooling option. The water pipes 192, preferably made of cooper, are embedded in the module frame 82. Cold water enters the pipe from one end, circulates through the frame picking-up the heat and comes out hot at the other end.

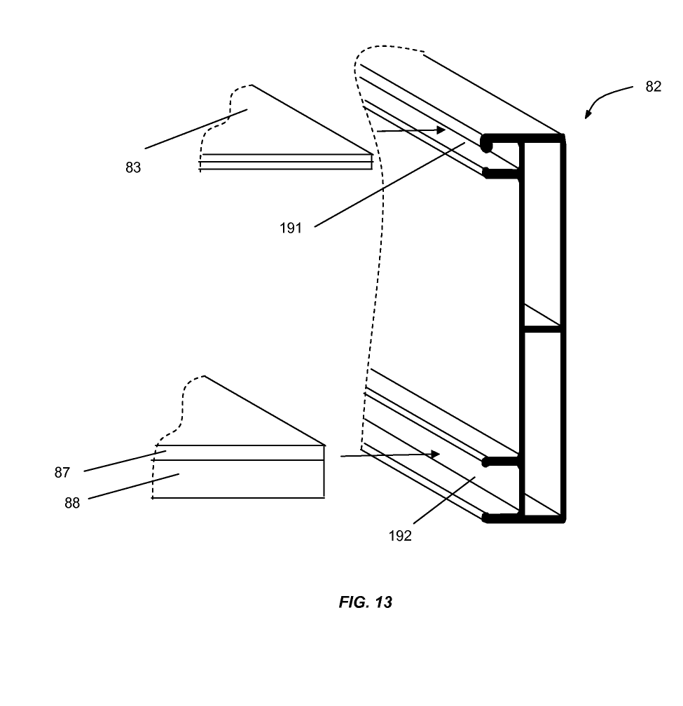

A brief description of the module assembly method is now presented. The use of common materials and standard assembly methods makes this module highly attractive for manufacturing in any part of the world with no skilled labor. There are 2 main sub-assemblies in this CPV module, the concentrating optics and the generator circuit. In the optics sub-assembly, the Fresnel lenses are created out of a single sheet of optical acrylic material which is mounted directly to the module frame. In the signal generator subassembly shown in FIG. 12, the cells 84 are first attached to the carrier strip 136 by manual or automated methods. Next the heat spreader 87 is attached to the metal base plate 88 and then the carrier strips are compression bonded to the heat spreader. Finally the flux homogenizer 85 is attached to the heat spreader. Now the entire sub-assembly is ready to be mounted directly under the Fresnel lenses by attaching it to the frame shown in FIG. 13. The edge of the Fresnel lens 83 is inserted into the top slot 191, while the base sub-assembly, which includes the base plate 88 and the heat spreader 87, is inserted into the bottom slot 192.

While various embodiments of the present invention have been shown and described here in, it will be obvious that such embodiments are provided by way of example only. Numerous variations, changes and substitutions may be made without departing from the invention herein. Moreover, when any range is understood to disclose all values therein and sub-ranges between any two numerical values with the range including the endpoints. Accordingly, it is intended that the invention be limited only by the spirit and scope of the appended claims.

That which is claimed is:

1) A Concentrating Photovoltaic (CPV) module comprising:
a plurality of multi-junction solar cells receiving photons from the sun under high concentration delivered by one or more Fresnel lenses and a secondary reflective or refractive flux homogenizer; said solar cells are mounted on CTE matched carrier strips, which provide low loss cell-to-cell electrical connections, that are directly bonded to a light weight graphite heat spreader, which is mounted on an aluminum honeycomb base plate; said base plate and lenses are assembled together using an aluminum frame.

2) A Concentrating Photovoltaic (CPV) module according to claim 1, wherein a multi-lens optical systems comprises positive, negative, flat, curved or dome shaped Fresnel lenses stacked to reduces the sun concentrator focal length resulting in thin CPV modules

3) A Concentrating Photovoltaic (CPV) module according to claim 1, wherein a combination of positive, negative and shaped Fresnel lenses that enables low to medium sun concentration for fixed module installation without sun tracking

4) A Concentrating Photovoltaic (CPV) module according to claim 1, where in the Multi-lens optical system provides up to 1000:1 sun concentration.

5) A Concentrating Photovoltaic (CPV) module according to claim 1, wherein a secondary concentrator is used as a flux homogenizer on top of each solar cell to create a uniform flux; said homogenizer is comprised of a square kaleidoscope and mounting legs to attach the kaleidoscope to the solar cells' carrier board.

6) A Concentrating Photovoltaic (CPV) module according to claim 1, wherein a secondary reflective or refractive concentrator is used to increase the module sun acceptance angle and reduce the solar tracker accuracy to over +/−0.5 degrees.

7) A Concentrating Photovoltaic (CPV) module according to claim 1, wherein the solar cells are mounted on a CTE matched carrier strips using solder or compliant epoxy; said carrier strips also comprise printed circuits that provide low loss electrical cell-to-cell connectivity without wires.

8) A Concentrating Photovoltaic (CPV) module according to claim 1, wherein the solar cells are made of triple junction InGaP/InGaAs/Ge semi-conductor material having an efficiency approaching 40% under 500 times sun concentration.

9) A Concentrating Photovoltaic (CPV) module according to claim 1, wherein the carrier strips are directly bonded to a light weight, thin graphite heat spreader having up to 500 W/mK thermal conductivity; said spreader is bonded to a thin aluminum plate for stiffness, support and additional heat spreading.

10) A Concentrating Photovoltaic (CPV) module according to claim 1, wherein the graphite heat spreader and aluminum base plate are mounted to an aluminum frame, for support and additional heat sinking.

11) A Concentrating Photovoltaic (CPV) module according to claim 1, wherein the aluminum frame can accept additional heat fins for increasing thermal efficiency.

12) A Concentrating Photovoltaic (CPV) module according to claim 1, wherein the aluminum frame can include a liquid circulation system for increased thermal efficiency.

13) A Concentrating Photovoltaic (CPV) module according to claim 1, wherein solar module can use either air or liquid cooling methods without requiring design changes

14) A Concentrating Photovoltaic (CPV) module according to claim 1, where in all parts of the module can be manufactured using standard assembly techniques which allows automated high-volume surface mount (SMT) robotic assembly and ability to manufacture anywhere in the world with very little capital expenditure

15) A Concentrating Photovoltaic (CPV) module according to claim 1, wherein the high efficiency of the multi-junction solar cells (approaching 40%) and compact panel size reduces the space required to generate a given amount of electricity from solar power by at least a factor of 2 as compared to typical flat Silicon solar panels which have efficiencies of about 15%.

16) A light weight concentrating Photovoltaic (CPV) module for generating electric power at low cost comprising of:
a light weight metal frame typically manufactured using extrusion methods to minimize cost,
a single or a plurality of refractive Fresnel lenses to concentrate the sun on to the solar cells;
a secondary reflective or refractive flux homogenizer is used to create a uniform solar flux over the solar cells and reduce the sun tracking accuracy;
a carrier board formed of dielectric material with matched coefficient of thermal expansion (CTE) and having at least one solar cells mounted thereon;
a base plate formed of light weight honeycomb metal with a high rigidity, stiffness and thermal conductivity;
a graphite heat spreader positioned between said base plate and carrier board to remove the heat from the solar cells;

17) A Concentrating Photovoltaic (CPV) module according to claim 15, wherein the flux homogenizer is comprised of a kaleidoscope and mounting legs used to surface mount the homogenizer to the carrier board on top of the solar cells.

18) A Concentrating Photovoltaic (CPV) module according to claim 15, wherein the base plate is constructed from a honeycomb structure that provide stiffness, strength, heat dissipation, corrosion protection and vibration dampening to the solar module.

19) A method of generating electric power at low cost from CPV modules by:
Maintaining high solar cell conversion efficiency, even under 500 times sun, by removing the heat from the solar cells using graphite heat spreading material which limits the temperature rise to less than 15 degree Celsius, reducing the cell-to-cell connectivity losses by using low resistance wide copper traces on a circuit board material,
using CTE matched carrier material to reduce stress on the solar cells and thereby increasing reliability,
and using low cost common type materials and assembly techniques that do not require special assembly equipment
